(19) United States
(12) Patent Application Publication
(10) Pub. No.: US 2011/0194355 A1
(43) Pub. Date: Aug. 11, 2011

(54) VERIFY WHILE WRITE SCHEME FOR NON-VOLATILE MEMORY CELL

(75) Inventor: Chen-Hao Po, Taipei County (TW)

(73) Assignee: eMemory Technology Inc., Hsinchu (TW)

(21) Appl. No.: 12/702,258

(22) Filed: Feb. 8, 2010

(51) Int. Cl. G11C 16/06

(52) U.S. Cl. 365/185.22

(57) ABSTRACT

A verify while write (VWW) scheme for a non-volatile memory (NVM) cell is provided. The VWW scheme conducts simultaneous write and verify operation by sensing the memory cell current during the write pulse at exactly the same write bias condition in contrast to the “verify+retry-write” write algorithm in the prior art. The VWW scheme removes the iterative “verify and then retry-write” to save both control timing and power consumed in these iterations. Instead, the VWW scheme is composed of single write pulse only in the entire algorithm with exact write pulse width trimmed automatically for multiple memory cells undergoing parallel writing within one write command assertion. Faster write speed, more power efficient write operation and higher reliability of non-volatile semiconductor memory cell are thus achieved with the VWW scheme in this present disclosure.

### BACKGROUND OF THE DISCLOSURE

1. Field of the Disclosure

The present disclosure generally relates to a memory, and more particularly, to a verify while write scheme for a non-volatile memory (NVM) cell.

2. Description of Related Art

A non-volatile memory (NVM) is a semiconductor memory that can retain the information stored therein even when the device having the NVM is not powered. Examples of NVM include mask read-only memories (mask ROMs), programmable read-only memories (PROMs), erasable programmable read-only memories (EPROMs), electrically erasable programmable read-only memories (EEPROMs), and flash memories, etc. NVM is broadly applied in the semiconductor industry and has been developed into a memory that can prevent loss of programmed data, such as the firmware storage for electronic devices, and the data storage for digital still camera photography, for portable audio and video devices, and for the most recently emerging trend of solid-state disk-drive (SSD) for either personal desktop computing purpose or notebook computing purpose. Despite the diverse fields of application for NVM storage, they share quite a common target performance requirement from the fast-growing mobile/portable application. That is, faster speed of writing into the NVM and more power-efficient operation of this writing procedure comprise most essential performance targets for the NVM at the present and of the future generation. A NVM is usually programmed, read, and/or erased according to the ultimate purpose thereof in a device, and data programmed in the NVM can be kept for a long time.

However, based on the general classification for present mainstream NVM array architectures, all of the NOR-type, NROM-type, and the most popular NAND-type NVM's suffer different obstacles to be removed if they attempt to further improve their present write-speed and write-power performance to meet more challenging specification in the future application. In a conventional flash memory, a tunnelling oxide layer is disposed on the substrate for insulating a floating gate, a control gate is disposed on the floating gate, and an inter-gate dielectric layer is disposed between the floating gate and the control gate. The flash memory is a stack-gate flash memory, the floating gate and the control gate are made of doped polysilicon, and a source region and a drain region are disposed at both sides of the substrate.

While writing data into the flash memory, the source and the substrate are grounded, and appropriate voltages are supplied to the control gate and the drain to inject electrons into the floating gate. While reading data from the flash memory, an appropriate operating voltage is supplied to the control gate. In this case, the electrified state of the floating gate affects the threshold voltage of the channel under the floating gate, and the data value is determined to be “0” or “1” according to the threshold voltage of the channel. In addition, while erasing data from the flash memory, the voltage level of the substrate, the drain (source) region, or the control gate is increased, and the electrons are released through tunneling effect from the floating gate to the substrate (i.e., substrate erase) or the drain (source) (i.e., drain (source) side erase) via the tunnelling oxide layer or to the control gate via the inter-gate dielectric layer.

While writing data into a flash memory, a programming operation is usually performed on the flash memory through a channel hot electron injection (CHEI) technique, so as to write the data into the flash memory. While erasing data from a flash memory, the electrons are pulled out from the floating gate into the channel via the tunnelling oxide layer through a Fowler Nordheim tunnelling technique.

In order to achieve a higher storage capacity and a smaller unit size, another type of NVM has been increasingly focused in recent years, wherein localized charge storage is adopted to store two data bits in each storage unit. In such a NVM, a non-conductive charge trapping layer is disposed between the channel and the gate, and ideally, between two dielectric layers (for example, silicon dioxide layers). This type of NVM is referred to as nitride read only memory (NROM) and which usually includes an oxide/nitride/oxide (ONO) charge trapping structure. A major advantage of such NVMs made of charge trapping materials falls on the localized charge storage which allows each storage unit to store two data bits. The localized charge storage allows one charge (bit−1) to be stored in the charge trapping layer within an area close to a source/drain region, and another charge (bit−2) to be stored in the charge trapping layer within an area close to another source /drain region.

Even though many different types of NVMs are developed along with the advancement of technologies, the method of programming these NVMs remains unchanged. FIG. 1 is a flowchart illustrating how conventionally a NVM cell is programmed. Referring to FIG. 1, first, in step S102, transfer a data to be written into NVM through in-chip write buffer so as to obtain the storage data. Then, in step S104, a programming voltage is set to a programming voltage configuration (a high level configuration) according to the storage data (i.e., establishing in-chip high voltage power supply to provide the essential bias for NVM writing device physics). Next, in step S106, the NVM cell is programmed to write the storage data into the NVM cell (i.e., alternate the storage state of NVM in response to the data to be written into the memory cell). After that, in step S108, the programming voltage is restored back to a non-programming voltage configuration (a low level configuration). In another word, recover the previously-established in-chip high voltage back to a usually much-lower condition for the subsequent verify read stage. Next, in step S110, the programmed NVM cell is verify read (i.e., perform internal read operation on the cells to be written to judge whether the data has been correctly written into them or not). It should be noted that in the step S106 for programming the NVM cell and the step S108 for verify reading the NVM cell, the bias applied to each end of the NVM cell is different. Namely, the operation performed on the NVM cell can be distinguished according to the bias applied to the each end of the NVM cell.

Thereafter, in step S112, whether the NVM cell is successfully programmed (whether the data is correctly written into the NVM cell) is determined according to the reading result. If the reading result is incorrect, the procedure returns to step S104 to set the programming voltage supplied to the NVM cell to the programming voltage configuration and execute the steps S106-S112 again. Obviously, an iteration composed of steps S104-S112 will form a close loop of internal write algorithm as long as the data is not yet correctly written into the NVM to be written. Therefore, iterative steps S104, S108 and S110 in the following retry programming loop are unnecessary overhead considering write control timing and write control vdd power consumption because these 3 stages do not perform actual write operation on NVM cells; instead, they either prepare the high voltage required by the subsequent actual writing process or attempt to judge whether the NVM cells have been correctly written or not. Contrarily, if it is determined in step S112 that the reading result obtained in step S110 is correct, the programming of the NVM cell is ended (step S114). The step S114 indicates the completion of the write command and perform mode exit of write operation to return a completion status back to the system that attempts to access this NVM.

In brief, we can easily infer that the aforementioned conventional NVM Write algorithm needs improvement to avoid these unnecessary overheads from control timing and power in its iterative manner termed as “Verify and then retry-Write” by those who are skilled in this art. However, for all of the NOR-type, NROM-type and the NAND-type NVM architecture, they have their own distinctive reasons that prevent them from adopting improved algorithm easily.

For example, FIG. 2 is a diagram of a conventional NVM cell programming device, wherein the NVM cell maybe such as NOR flash memory, NROM and NAND flash memory cell. Referring to FIG. 2, assume that the NVM cell 202 is a NOR flash memory cell. It meets challenges to adopt improved algorithm as shown below. First, while programming a NOR flash memory cell, the bias at the drain D1 of the memory cell is received from a high-level charge pump circuit (not shown). Thus, signal detection can not be performed on the drain D1 of the NOR flash memory cell (for either a voltage signal or a current signal from NVM array). Second, an in-chip ground level voltage VSS is supplied to the source S1 of the NOR flash memory, and no addressing operation is performed on the source S1. Thus, signal detection can not be performed on the source S1 (for either a voltage signal or a current signal from NVM array) since the memory cells cannot be distinguished from each other. Accordingly, the loop of foregoing steps S104-S112 still has to be executed to ensure that data is correctly into a NOR flash memory, and NOR flash memory cell current at write bias condition during the previously-mentioned step S106 of program cell is “dumped” into the source-terminal power supply VSS except for the write physics related to this cell current like channel hot carrier injection device physics adopted to achieve alternation of NVM cell 202 storage state in this write operation. In brief, we can evaluate NOR-type NVM cell writing scheme as “adopting the straight-forward conventional Write control flow as explained from step S102 to S114 with its main disadvantage of unnecessary iterative overhead from both control timing and power consumption.

On the other hand, assume that the NVM cell 202 is a NROM cell. The problem in improving the programming of NROM is that the programming voltage supplied to the drain D1 of a NROM is also received from a high-level charge pump circuit and accordingly no signal detection can be performed on the drain D1 of the NROM (for either a voltage signal or a current signal from NVM array). And the in-chip ground level voltage VSS is supplied to the source S1 of the NROM cell. Because NROM-type NVM architecture applies memory address decoding to these source terminals, indeed it can perform source terminal signal sensing (for either a voltage signal or a current signal from NVM array) with source terminal address decoding for the purpose of memory cell distinction. Nevertheless, the bias at the source S1 of the NROM is 0V when the programming operation in step S106 is executed; any source terminal path voltage drop that leads to a non-zero-volt source terminal bias for NROM cells is regarded as a undesirable condition to negatively affect the writing characteristics for NROM cells from a point of view of NROM cell device physics. On the other hand, a zero-volt source terminal bias during step S106 of program cell can not enable the source terminal signal sensing (for either a voltage signal or a current signal from NVM array.

For example, voltage signal sensing requires a non-zero NVM array voltage signal to be compared with the reference voltage and current signal sensing requires a non-zero source terminal voltage level of at least saturation voltage for current mirror sensing block to function correctly). As a result, NROM cell current at write bias condition during the previously-mentioned step S106 of program cell is “dumped” into the source-terminal VSS power supply except for the write physics related to this cell current like channel hot carrier injection device physics adopted to achieve alternation of NROM cell storage state in this write operation. In brief, we can evaluate NROM-type NVM cell writing scheme as “adopting the straight-forward conventional Write control flow as explained from step S102 to S114 with its main disadvantage of unnecessary iterative overhead from both control timing and power consumption.

In addition, assume that the NVM cell 202 is a NAND flash memory cell. the problem in improving the programming of NAND flash memory is that the bias supplied to the drain D1 of a NAND flash memory is received from a writer buffer latch (not shown), and the bias supplied to the drain D1 is 0V when the programming operation in step S106 is executed, and the bias supplied to the source S1 of the NAND flash memory is received from an in-chip ground level voltage VSS. Even though the source S1 of the NAND flash memory is addressed, no signal detection can be performed on the source S1 of the NAND flash memory (for either a voltage signal or a current signal from NVM array). This is because the voltage difference between the drain D1 and the source S1 of the NAND flash memory is 0V (the voltages supplied to the drain D1 and the source S1 are both 0V) when the programming operation in step S106 is executed. As a result, the write physics based on Fowler-Nordheim tunneling will not generate any cell current along the bit line path, and hence of course neither drain D1 nor source S1 will have current signal available for sensing scheme during the step S106 of program cell. In brief, we can evaluate NAND-type NVM cell writing scheme as “adopting the straight-forward conventional Write control flow as explained from step S102 to S114 with its main disadvantage of unnecessary overhead from both control timing and power consumption.

### SUMMARY

The present disclosure of verify while write algorithm, serving as a novel write algorithm for NVM, can achieve the target performance requirement of faster write-speed and lower write-power consumption in a vivid contrast to any of the aforementioned NOR-type, NROM-type and NAND-type NVM architecture that adopt the conventional “verify and then retry write” write algorithm. And the verify-while-write (termed as VWW thereafter) algorithm has the primary features as follows:

<A> VWW verifies NVM cell current at exactly the same write bias condition defined for the NVM cell.

<B> in contrast to the conventional “verify and then retry-write” write algorithm, VWW algorithm performs simultaneous write and verify mechanism under the same write bias condition.

<C> in contrast to the conventional “verify and then retry-write” write algorithm, VWW algorithm performs single write pulse only of write bias condition to NVM cells without any iterative re-try write loop.

<D> in contrast to the conventional “verify and then retry-write” write algorithm, VWW algorithm saves write-speed and write-power consumption by removing the iterative stages of internal high voltage setup, internal high voltage recovery, verify READ after each write pulse of write bias, and the judging point to initiate the iterative flow.

<E> in contrast to the conventional “verify and then retry-write” write algorithm, VWW algorithm will set the drain terminal bias in floating state for NVM cell to be written at any time when the simultaneously-verified NVM cell voltage or current under write bias condition exceeds the pre-defined target write-completion NVM cell current/voltage.

In this way, with the help of this automatically self-trimming write pulse width of write bias condition for each of the multiple NVM cells undergoing parallel write operation within single write-command assertion, exact write pulse width for each NVM cells to be written is achieved and much better NVM cell operational reliability is thus obtained.

In brief, we can summarize this novel VWW algorithm as greatly-improved

NVM write algorithm to achieve faster write-speed, lower write-power consumption and higher NVM cell operational reliability in contrast to the conventional “verify and then retry-write” write algorithm.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a flowchart illustrating how conventionally a non-volatile memory (NVM) cell is written.

FIG. 2 is a diagram of a conventional NVM cell writing device.

FIG. 3 is a diagram of a NVM cell writing device according to an embodiment of the present disclosure.

FIG. 4 is a flowchart of verify while write scheme for a NVM cell according to an embodiment of the present disclosure.

FIG. 5 is a diagram of a NVM cell writing device according to another embodiment of the present disclosure.

FIG. 6A illustrates a waveform of a writing voltage in the conventional technique illustrated in FIG. 1.

FIG. 6B illustrates a waveform of a writing voltage in the embodiment illustrated in FIG. 4.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

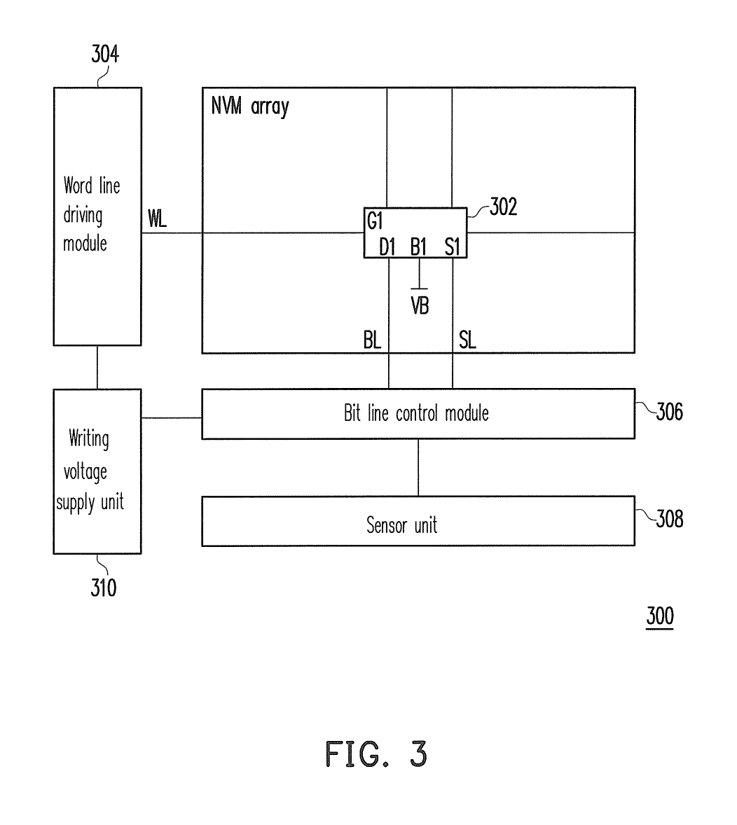

FIG. 3 is a diagram of a non-volatile memory (NVM) cell writing device according to an embodiment of the present disclosure. Referring to FIG. 3, the NVM cell writing device 300 includes a plurality of NVM cells 302, a word line driving module 304, a bit line control module 306, a sensor unit 308, and a writing voltage supply unit 310. Each of the NVM cells 302 includes a source S1, a drain D1, a gate G1, and a substrate B1. The NVM cells 302 may be NOR flash memory cells, NAND flash memory cells, or nitride read only memory (NROM) cells. In the present embodiment. The drains D 1 of the NVM cells 302 are respectively coupled to the bit line control module 306 through the drain bit lines BL, and the sources S1 thereof are coupled to the bit line control module 306 through the source bit lines SL, and the gates G1 thereof are coupled to the word line driving module 304 through the corresponding word lines WL. Besides, the substrates B1 of the NVM cells 302 are coupled to a substrate bias voltage VB, wherein the word line driving module 304 and the bit line control module 306 respectively control the voltage supplied to the NVM cell 302. The sensor unit 308 is coupled to the bit line control module 306 and detects an electric parameter (for example, a voltage value or a current value) of the NVM cells 302 through the bit line control module 306. The writing voltage supply unit 310 is coupled to the word line driving module 304 and the bit line control module 306, and which supplies a writing voltage (a high voltage) to the word line driving module 304 and the bit line control module 306 to drive (program) the NVM cells 302 when the NVM cells 302 are written. The writing operation discussed in the present embodiment refers to data programming and erasing operations. In other words, The operational bias condition for performing simultaneous write and verify NVM cell 302 is at exactly the same write bias condition, we have a word line terminal bias at write condition, a drain terminal bias at write condition, a source terminal bias at write condition and a substrate terminal bias at write condition. Note that in this write phase at the write bias condition. The sensor unit 308 is turned ON while the writing voltage supply unit 310 is also turned ON simultaneously.

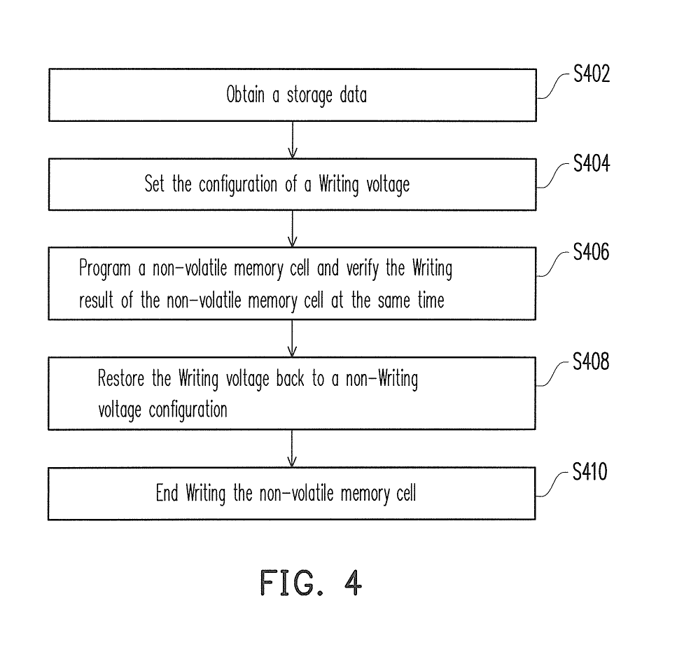

FIG. 4 is a flowchart of verify while write scheme for a NVM cell according to an embodiment of the present disclosure. Below, the verify while write scheme will be described with reference to the NVM cell writing device 300 illustrated in FIG. 3. Referring to both FIG. 3 and FIG. 4, first, in step S402, transfer a data to be written into NVM through in-chip write buffer (not shown) so as to obtain the storage data. Then, in step S404, the writing voltage supply unit 310 sets the configuration of the writing voltage according to the storage data and provides the writing voltage to the word line driving module 304 and the bit line control module 306 to be used for writing the NVM cells 302. If the writing operation to be performed is an erasing operation or a reset operation, step S402 is skipped, and in step S404, the word line driving module 304 and the bit line control module 306 outputs a writing voltage of an erasing configuration to the NVM cells 302.

It should be noted that when the writing voltage supply unit 310 starts to build up the high-level writing voltage, the sensor unit 308 is turned on and starts to detect the electric parameter of the NVM cells 302 at the same time. Accordingly, when the word line driving module 304 and the bit line control module 306 program the NVM cells 302, the sensor unit 308 can detect the electric parameter of the NVM cells 302 via the drain bit lines BL, so as to verify the writing result of the NVM cells 302 (step S406). Step S406 determine whether the NVM cells 302 has been successfully programmed. The electric parameter may be a voltage or an writing current. For example, the sensor unit 308 can detect the variation of writing current on the drain bit lines BL, and determine whether the writing current of the NVM cells 302 reaches a predetermined level when the word line driving module 304 and the bit line control module 306 outputs the writing voltage in the erasing configuration (or a writing configuration) to the NVM cells 302.

The writing voltage may be a voltage pulse. In this case, the sensor unit 308 verifies the NVM cells 302 during the pulse duration of the writing voltage. Because the writing result of the NVM cells 302 is reflected in the output electric parameter of the NVM cells 302, when the sensor unit 308 detects that the electric parameter (e.g. writing current) of one of the NVM cells 302 reaches a predetermined level (i.e., the sensor unit 308 determines that the writing of the NVM cell 302 is already completed), the bit line control module 306 disables the NVM cell 302, and the writing of the other NVM cells 302 is continued. As described above, the sensor unit 308 monitors the writing progresses of the NVM cells 302 and individually disables those successfully written NVM cells 302 according to their writing progresses. The NVM cells 302 may be disabled by removing the writing voltage supplied to the NVM cells 302 (i.e., the bit line control module 306 is stopped from outputting the writing voltage to the corresponding NVM cells 302).

The NVM cells 302 on the same word line WL may be written at different speeds. Namely, the writing of some NVM cells 302 is completed earlier than that of other NVM cells 302 on the same word line WL. Conventionally, the writing voltage is removed after the writing of all the NVM cells 302 is completed. Thus, those NVM cells 302 that are written at faster speeds consume power unnecessarily before the writing voltage is removed. Those written NVM cells 302 continue to receive the writing voltage from the word line driving module 304 and the bit line control module 306 before the writing of other NVM cells 302 is completed. As a result, the lifespan of the NVM cells 302 is shortened. Through the verify while write scheme in the present embodiment, the writing voltage is individually removed once a NVM cell 302 is written so that the time for the NVM cell 302 to receive the writing voltage is shortened and accordingly the lifespan thereof is prolonged. In addition, the power consumption is reduced since the writing voltage is removed from those NVM cells 302 that are written at faster speeds.

Finally, after the NVM cells 302 are written and verified simultaneously, the writing voltage supply unit 310 reduces the writing voltage to restore it to a non-writing voltage configuration (step S408). By now, the writing operation of the NVM cells 302 is completed (step S410) and no additional verification step is to be executed.

In foregoing step S406, the data writing situation of the NVM cells 302 is verified at the same time when the storage data is written into the NVM cells 302. Thus, the situation of repeatedly executing the steps of setting the configuration of the writing voltage (a high level configuration), writing the storage data into the NVM cells 302, restoring the writing voltage back to a non-writing voltage configuration (a low level configuration), and verifying the writing result in the conventional technique is avoided, so that both the power consumption and the writing time are reduced. In addition, during the writing process, the writing charges passing through the NVM cells 302 are used by the sensor unit 308 (i.e., for detecting the voltage or current of the NVM cells 302), so that the power is used more efficiently and the writing charges won't be wasted as in the conventional technique.

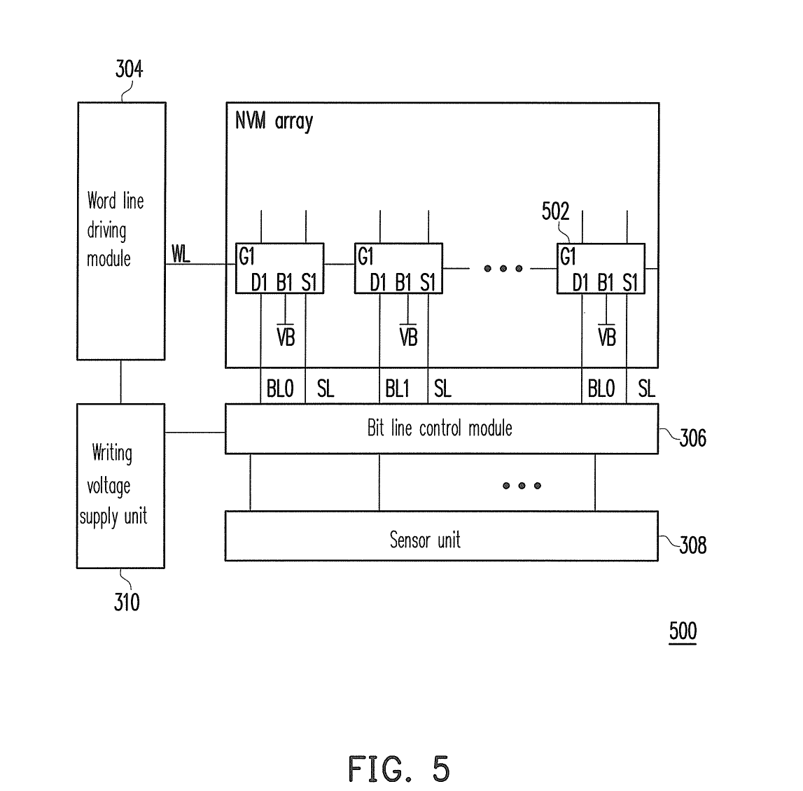

To be specific, the NVM cell writing device may be as illustrated in FIG. 5. FIG. 5 is a diagram of a NVM cell writing device according to another embodiment of the present disclosure. Referring to FIG. 5, the difference of the NVM cell writing device 500 in the present embodiment from the NVM cell writing device 300 in FIG. 3 is that each of the NVM cells 502 includes a source S1, a drain D1, a gate G1, and a substrate B1. In the present embodiment, there are 8 NVM cells 502 to be written with given data on each word line WL. However, the present disclosure is not limited thereto, and in an actual application, there may also be 16, 32, or any other number of NVM cells on each word line. Referring to FIG. 5, the drains D1 of the NVM cells 502 are respectively coupled to the bit line control module 306 through the drain bit lines BL0-BL7, and the sources Si thereof are coupled to the bit line control module 306 through the source bit lines SL, and the gates G1 thereof are coupled to the word line driving module 304 through the corresponding word lines WL. Besides, the substrates B1 of the NVM cells 502 are coupled to a substrate bias voltage VB.

In the embodiment illustrated in FIG. 5, the verify while write scheme adopted by the NVM cell writing device 500 may also be implemented based on the steps illustrated in FIG. 4. For example, in step S406, if a digital data “00000000” is to be written, the word line driving module 304 and the bit line control module 306 are controlled to set the substrate bias voltage VB and the writing voltage on the source bit lines SL, the word lines WL, and the drain bit lines BL0-BL7 to a writing voltage configuration. In other words, the word line terminal bias, the drain terminal bias, the source terminal bias and the substrate terminal bias of the 8 NVM cells 502 are at write condition. For example, the substrate bias voltage VB and the voltage on the source bit lines SL are both set as the ground voltage, and the voltages on the word lines WL and the drain bit lines BL0-BL7 are set as the writing voltage (for example, 12V, supplied by the writing voltage supply unit 310). The digital data “00000000” is written into the 8 NVM cells 502 on the same word line WL by controlling all the 8 NVM cells 502 to capture the electrons.

It should be noted that in the present embodiment, same as in the embodiment illustrated in FIG. 4, when the writing voltage supply unit 310 starts to build up the high level writing voltage, the sensor unit 308 is turned on and starts to detect an electric parameter on the drain bit lines BL0-BL7 at the same time. In this write phase at the write bias condition, the sensor unit 308 is turned on while the writing voltage supply unit 310 is also turned on simultaneously. With the writing voltage supply unit 310 as described above, simultaneous write operation and verify operation are conducted on 8 NVM cells 502 of the same word line WL, termed as a “byte of the address to be written”. When the sensor unit 308 detects that the electric parameter from a specific bit line among the drain bit lines BL0-BL7 reaches a predetermined condition, the bit line control module 306 disables the corresponding NVM cell 502 from its previous drain terminal bias in write condition.

For example, referring to FIG. 5, assuming that the writing of the NVM cell 502 coupled to the drain bit line BL0 is completed, the electric parameter (for example, a voltage value or a current value) of the drain bit line BL0 then reaches a particular predetermined level. After the sensor unit 308 detects that the electric parameter of the drain bit line BL0 reaches the predetermined level, the bit line control module 306 stops outputting the writing voltage to the drain bit line BL0 so that the drain D1 of the corresponding NVM cell 502 is floated and accordingly the writing of the NVM cell 502 is stopped. In other words, the NVM cell 502 corresponding to the drain bit line BL0 has exceeded the predefined judging criteria for the sensor unit 308 and hence its drain bit line bias is changed into a “floating state” such that its drain terminal write bias condition is removed and the NVM cell 502 corresponding to the drain bit line BL0 thus exits its write operation and a source terminal bias at write condition and a substrate terminal bias at write condition. Meanwhile, the voltages on each end of other unfinished NVM cells 502 is still the writing voltage configuration (i.e., the word line terminal bias, the drain terminal bias, the source terminal bias and the substrate terminal bias of the other unfinished NVM cells 502 are still at write condition) until the storage data is completely written into the NVM cells 502 (the electric parameter of each of the drain bit lines BL0-BL7 reaches the predetermined level and accordingly the corresponding drain is floated) and the writing of the current word is ended (i.e., once one or multiple of the 8 NVM cells 502 to be written meet the predefined sensing criteria of the sensor unit 308, its or their drain terminal (drain bit line correspondently) bias condition is set to floating and thus exits the write operation while others are still in write operation).

Additionally, the electric parameter detected by the sensor unit 308 may vary along different technique for realizing the NVM cells 502. For example, the electric parameter detected by the sensor unit 308 is a current value when the NVM cells 502 are flash memory cells or NROM cells, and the electric parameter detected by the sensor unit 308 is a voltage value when the NVM cells 502 are NAND flash memory cells.

Similarly, in step S408, after all the 8 NVM cells 502 on the word line WL are written, the writing voltage supply unit 310 reduces the writing voltage to restore it to a non-writing voltage configuration.

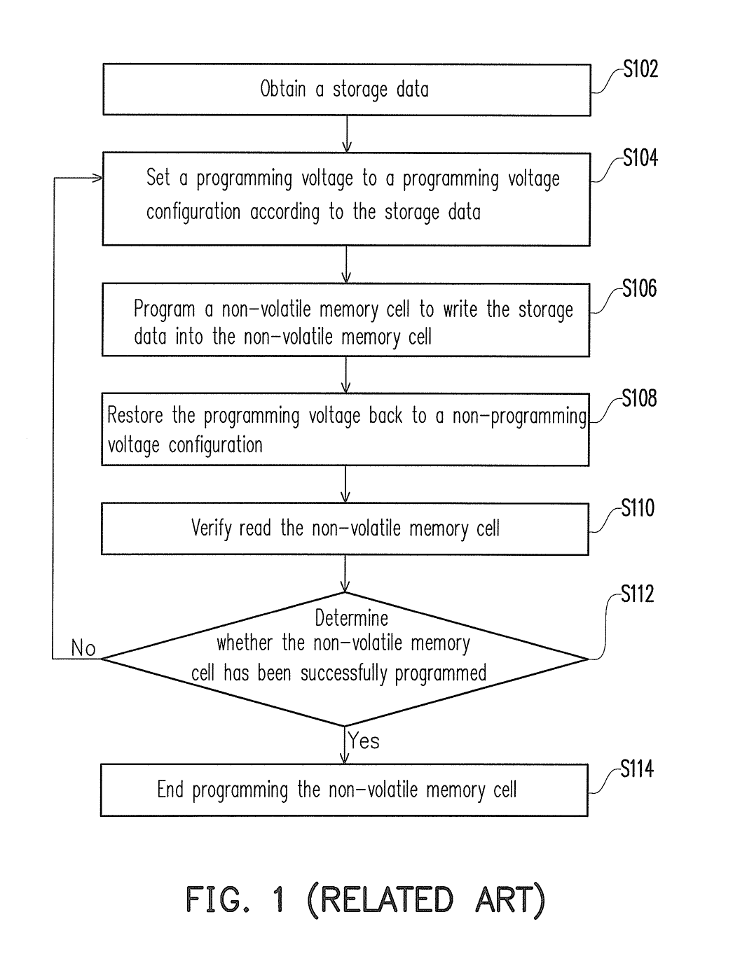

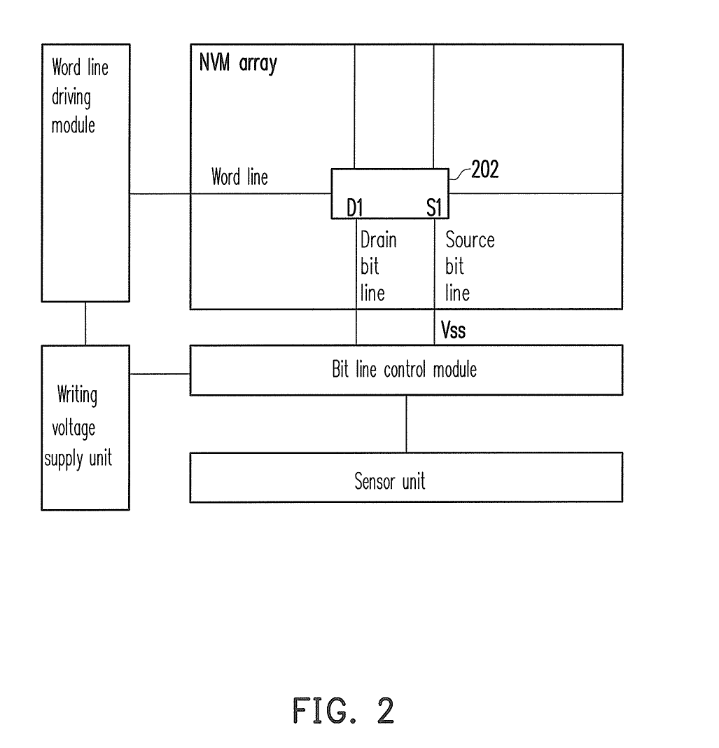

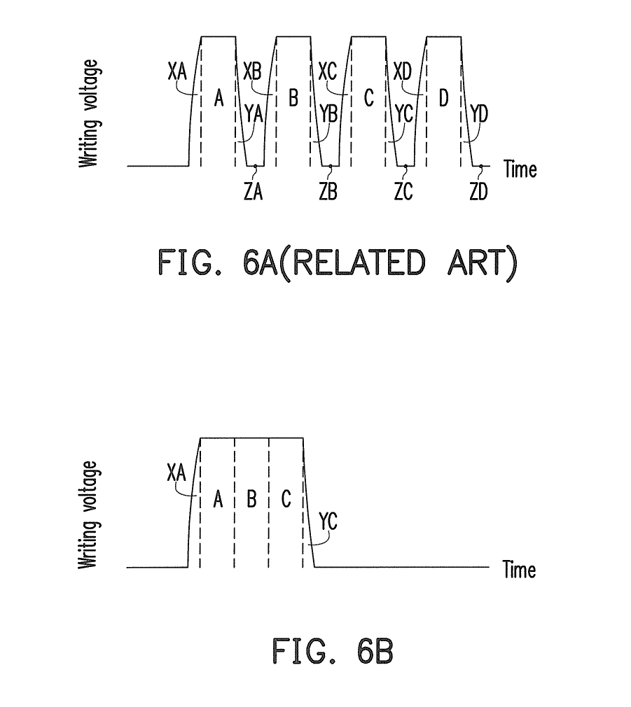

FIG. 6A illustrates a waveform of the writing voltage in the conventional technique illustrated in FIG. 1. The A˜D in the FIG. 6A illustrates 4 times of retry programming step S106 in the FIG. 1. The A˜D may be extended to any retry number. The XA˜XD in the FIG. 6A illustrates 4 times of retry step S104 in the FIG. 1. The YA˜YD in the FIG. 6A illustrates 4 times of retry step S108 in the FIG. 1. The ZA˜ZD in the FIG. 6A illustrates 4 times of retry “post-write verify operation” (i.e. step S110 in the FIG. 1).

FIG. 6B illustrates a waveform of the writing voltage in the embodiment illustrated in FIG. 4. It can be understood by comparing FIG. 6A and FIG. 6B that in the verify while write scheme illustrated in FIG. 4, only XA and YC are left, even actual write pulse may be reduced from A+B+C+D to only A+B+C while XB˜XD, YA, YB, YD, ZA˜ZD and D are completely removed to save control timing and power in a self-evident manner. The configuration of the writing voltage output by the writing voltage supply unit is set only once (i.e., to a high level writing voltage), and the writing of data and the verification of the writing result are then carried out simultaneously, while in the conventional technique, the writing voltage is boosted and reduced repeatedly. The verify while write scheme illustrated in FIG. 4 saves unnecessary timing and power overhead of iterative HV setup (S104), high voltage recovery (S108)/Verify READ (S110). Obviously, the aforementioned iterative step S104, S108 and S110 are removed and hence the time for writing the data is greatly shortened and the power consumption is significantly reduced.

As described above, in the present disclosure, the writing of a NVM cell and the verification of the writing result are carried out at the same time so that the power consumption is significantly reduced and the time for storing data is greatly shortened. In addition, a sensor unit receives the current passing through a NVM cell when the NVM cell is written as the operating power of the sensor unit, so that the power supply can be used more efficiently. Moreover, the writing voltage is removed after the writing of a NVM cell is completed so that the time for the NVM cell to receive the writing voltage is shortened and accordingly the lifespan of the NVM cell is prolonged.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A verify while write scheme for a non-volatile memory (NVM) cell, comprising:
supplying a writing voltage to the NVM cell for writing a storage data into the NVM cell; and
verifying a writing result of the NVM cell by detecting an writing current of the NVM cell at the same time when the writing voltage is supplied to the NVM cell.

2. The verify while write scheme according to claim 1, wherein before the step of supplying the writing voltage to the NVM cell, the verify while write scheme further comprises:
obtaining the storage data; and
setting a configuration of the writing voltage according to the storage data.

3. The verify while write scheme according to claim 1 further comprising:
restoring the writing voltage to a non-writing voltage configuration after the writing result of the NVM cell is verified.

4. The verify while write scheme according to claim 1, wherein the step of verifying the writing result of the NVM cell further comprises:
disabling the NVM cell when the writing current of the NVM cell reaches a predetermined level.

5. The verify while write scheme according to claim 4, wherein the step of disabling the NVM cell comprises:
removing the writing voltage supplied to the NVM cell.

6. The verify while write scheme according to claim 1, wherein the writing voltage is a voltage pulse.
